(19) United States
(12) Patent Application Publication
(10) Pub. No.: US 2024/0120352 A1
(43) Pub. Date: Apr. 11, 2024

(54) AVALANCHE PHOTODETECTION DEVICE, ELECTRONIC DEVICE, AND LiDAR DEVICE

(71) Applicant: KOREA INSTITUTE OF SCIENCE AND TECHNOLOGY, Seoul (KR)

(72) Inventor: Myung-Jae LEE, Seoul (KR)

(21) Appl. No.: 18/308,236

(22) Filed: Apr. 27, 2023

(30) Foreign Application Priority Data
Oct. 7, 2022 (KR) 10-2022-0128721

(51) Int. Cl. H01L 27/146; G01S 7/481

(52) U.S. Cl. CPC H01L 27/1461; G01S 7/4816; H01L 27/14627; H01L 27/1463; H01L 27/14636

(57) ABSTRACT

Disclosed is an avalanche photodetection device that comprises a photodetection layer, the photodetection layer includes a first well, a heavily doped region provided on the first well, and an anode contact spaced apart from the heavily doped region, a conductivity type of the first well and the anode contact is p-type, a conductivity type of the heavily doped region is n-type, the heavily doped region is configured to be biased with a positive bias, the anode contact is configured to output a signal.

### CROSS-REFERENCE TO RELATED APPLICATIONS

This application claims priority under 35 U.S.C. § 119 to Korean Patent Application No. 10-2022-0128721 filed on Oct. 7, 2022, in the Korean Intellectual Property Office, the disclosures of which are incorporated by reference herein in their entireties.

### BACKGROUND

### 1. Technological Field

Embodiments of the present disclosure described herein relate to avalanche photodetection device, electronic device, and LiDAR device.

The inventors acknowledge the financial support from the Korea Institute of Science and Technology (KIST) Institution Program (Grant No. 2E32242) and the National Research Foundation of Korea (NRF) (Grant No. 2021M3D1A2046731).

### 2. Description of the Related Art

The avalanche photodetection device is a photodetection device using avalanche multiplication. For example, the avalanche photodetection device includes an avalanche photodiode (APD) and a single-photon avalanche diode (SPAD). The avalanche photodetection device includes a photodiode and a circuit for controlling the photodiode. When the photodiode and the circuit are formed side by side on the same substrate, the avalanche photodetection device can be referred to as a two-dimensional avalanche photodetection device. When the photodiode and the circuit are formed on different substrates stacked, the avalanche photodetection device may be referred to as a three-dimensional avalanche photodetection device.

An avalanche photodiode (APD) is a solid-state photodetection device in which a high bias voltage is applied to the pn junction to provide high gain due to avalanche multiplication. When a photon with enough energy to release the electron reaches the photo diode, an electron-hole pair (EHP) is generated. The high electric field accelerates the photo-generated electrons quickly to (+) side, and the additional electrons-hole pairs are generated in succession by the impact ionization by such acceleration electrons. And then the electrons accelerate to the anode. Similarly, the holes are accelerated quickly toward (−) side and causes the same phenomenon. This process repeats the avalanche multiplication of light-generated electrons. Thus, APD is a semiconductor-based device that operates similarly to photomultiplier tubes. The linear mode APD is an effective amplifier that can control the bias voltage to set a gain and obtain tens of to thousands of gains in linear mode.

Single Photon Avalanche Diode (SPAD) is an APD in which the P-N bonding part is biased more than breakdown voltage to operate in the GEIGER mode. SPAD can generate a very large current, and as a result, a pulse that can be easily measured with a quenching resistor (or quenching circuit) can be obtained. That is, the SPAD operates as a device that generates a large pulse compared to the linear mode APD. After the triggering the Avalanche, the quenching resistance or the quenching circuit is used to reduce the bias voltage under the breakdown voltage for quenching the Avalanche process. Once the Avalanche Process is quenched, the bias voltage is rising back over the breakdown voltage so that the SPAD is reset for the detection of another photon.

An avalanche photodiode or single photon avalanche diode can be integrated in three dimensions by forming most or all of the circuitry and other substrates. For example, single photon avalanche diode elements are formed by being arranged in an array form on one substrate, and a quenching circuit and other pixel circuits (eg, reset or recharge circuits, memories, amplification circuits, counters, gate circuits, time-to-digital converters, etc.) are formed on other substrates. Accordingly, a three-dimensionally integrated avalanche photodetection device of a back-side illumination (BSI) method or a front-side illumination (FSI) method is formed. In general, in the case of a 3D avalanche photodetection device, a negative bias is applied to an anode and an output is read through a cathode. In some example embodiments, a negative bias voltage source or power supply circuit is required, and the pixel circuit may become complicated or inefficient.

### SUMMARY

Embodiments of the present disclosure provide an avalanche photodetection device, an electronic device, and a LIDAR device using a positive bias, a simple and efficient voltage source or power circuit, a simple and efficient pixel circuit.

According to an embodiment, an avalanche photodetection device comprises a photodetection layer, the photodetection layer includes a first well, a heavily doped region provided on the first well, and an anode contact spaced apart from the heavily doped region, a conductivity type of the first well and the anode contact is p-type, wherein a conductivity type of the heavily doped region is n-type, the heavily doped region is configured to be biased with a positive bias, the anode contact is configured to output a signal.

According to further aspects of the invention, the anode contact surrounds the heavily doped region.

According to further aspects of the invention, the photodetection layer further includes a second well provided between the first well and the heavily doped region, a conductivity type of the second well is n-type, a doping concentration of the second well is lower than a doping concentration of the heavily doped region, the first well and the second well are directly contact with each other to form a depletion region.

According to further aspects of the invention, the second well extends to a region between the heavily doped region and the anode contact.

According to further aspects of the invention, the first well extends to a region between the second well and the anode contact.

According to further aspects of the invention, the photodetection layer further includes a relief region directly contacting the contact, a conductivity type of the relief region is p-type, a doping concentration of the relief region is lower than a doping concentration of the contact and higher than a doping concentration of the first well.

According to further aspects of the invention, the photodetection layer further includes an additional relief region provided on a bottom surface of the relief region, a conductivity type of the additional relief region is p-type, the additional relief region is formed to a position deeper than the first well.

According to further aspects of the invention, the photodetection layer further includes a guard ring extending from a region on a side surface of the heavily doped region to a region on a side surface of the first well, a conductivity type of the guard ring is n-type, a doping concentration of the guard ring is lower than a doping concentration of the heavily doped region.

According to further aspects of the invention, the avalanche photodetection device further comprises a control layer provided on the photodetection layer, the control layer includes a first circuit configured to bias the heavily doped region, and a second circuit configured to output the signal from the contact.

According to further aspects of the invention, the avalanche photodetection device further comprises a connection layer provided between the control layer and the photodetection layer, the connecting layer includes a first conductive line configured to electrically connect the heavily doped region and the first circuit, and a second conductive line configured to electrically connect the anode contact and the second circuit.

According to an embodiment, an electronic device comprises an avalanche photodetection device including a photodetection layer, the photodetection layer includes a first well, a heavily doped region provided on the first well, and an anode contact spaced apart from the heavily doped region, the first well and the anode contact have a p-type conductivity type, the heavily doped region has an n-type conductivity, the heavily doped region is configured to be biased with a positive bias, and the anode contact is configured to output a signal.

According to an embodiment, a LiDAR device comprises an electronic device including an avalanche photodetection device, the avalanche photodetection device includes a photodetection layer, the photodetection layer includes a first well, a heavily doped region provided on the first well, and an anode contact spaced apart from the heavily doped region, the first well and the anode contact have a p-type conductivity type, the heavily doped region has an n-type conductivity, the heavily doped region is configured to be biased with a positive bias, and the anode contact is configured to output a signal.

### BRIEF DESCRIPTION OF THE FIGURES

The above and other objects and features of the present disclosure will become apparent by describing in detail embodiments thereof with reference to the accompanying drawings.

FIG. 1 is a plan view of an avalanche photo detecting element according to an exemplary embodiment.

FIG. 2 is a cross-sectional view of the avalanche photo detecting element of FIG. 1 taken along line A-A′.

FIG. 3 is a plan view of the avalanche photodetection device of FIG. 2 according to an exemplary embodiment.

FIG. 4 is a plan view of the avalanche photodetection device of FIG. 2 according to an exemplary embodiment.

FIG. 5 is a plan view of the avalanche photodetection device of FIG. 2 according to an exemplary embodiment.

FIG. 6 is a plan view of the avalanche photodetection device of FIG. 2 according to an exemplary embodiment.

FIG. 7 is a plan view of the avalanche photodetection device of FIG. 2 according to an exemplary embodiment.

FIG. 8 is a plan view of the avalanche photodetection device of FIG. 2 according to an exemplary embodiment.

FIG. 9 is a cross-sectional view corresponding to line A-A′ of the avalanche photodetection device of FIG. 1.

FIG. 10 is a plan view of an avalanche photodetection device according to an exemplary embodiment.

FIG. 11 is a cross-sectional view of the avalanche photodetection device of FIG. 10 taken along line B-B′.

FIG. 12 is a cross-sectional view corresponding to line B-B′ of the avalanche photodetection device of FIG. 10.

FIG. 13 is a cross-sectional view corresponding to line B-B′ of the avalanche photodetection device of FIG. 10.

FIG. 14 is a cross-sectional view corresponding to line B-B′ of the avalanche photodetection device of FIG. 10.

FIG. 15 is a cross-sectional view corresponding to line B-B′ of the avalanche photodetection device of FIG. 10.

FIG. 16 is a cross-sectional view corresponding to line B-B′ of the avalanche photodetection device of FIG. 10.

FIG. 17 is a cross-sectional view corresponding to line B-B′ of the avalanche photodetection device of FIG. 10.

FIG. 18 is a plan view of an avalanche photodetection device according to an exemplary embodiment.

FIG. 19 is a cross-sectional view of the avalanche photodetection device of FIG. 18 taken along line C-C′.

FIG. 20 is a plan view of an avalanche photodetection device according to an exemplary embodiment.

FIG. 21 is a cross-sectional view of the avalanche photodetection device of FIG. 20 taken along line D-D′.

FIG. 22 is a plan view of an avalanche photodetection device according to an exemplary embodiment.

FIG. 23 is a cross-sectional view of the avalanche photodetection device of FIG. 22 taken along line E-E′.

FIG. 24 is a plan view of an avalanche photodetection device according to an exemplary embodiment.

FIG. 25 is a cross-sectional view of the avalanche photodetection device of FIG. 24 taken along line F-F′.

FIG. 26 is a plan view of an avalanche photodetection device according to an exemplary embodiment.

FIG. 27 is a cross-sectional view corresponding to the line G-G′ of the avalanche photodetection device of FIG. 26

FIG. 28 is a plan view of an avalanche photodetection device according to an exemplary embodiment.

FIG. 29 is a cross-sectional view corresponding to line H-H′ of the avalanche photodetection of FIG. 28.

FIG. 30 is a cross-sectional view of an avalanche photodetector according to an exemplary embodiment.

FIG. 31 is a top view of an avalanche photodetector array according to an exemplary embodiment.

FIG. 32 is cross-sectional views taken along the line J-J′ of FIG. 31.

FIG. 33 is a block diagram for describing an electronic device according to an exemplary embodiment.

FIGS. 34 and 35 are conceptual diagrams illustrating cases in which a LiDAR device according to an exemplary embodiment is applied to a vehicle.

### DETAILED DESCRIPTION

Hereinafter, with reference to the accompanying drawings, the embodiments of the present disclosure will be described in detail. In the following drawings, the same reference code refers to the same component, and the size of each component in the drawings may be exaggerated for the clarity and convenience of the description. On the other hand, the embodiments described below are only an example, and various variations are possible from these embodiments.

Hereinafter, what is described as “on” may include not only being directly on contact but also being on non-contact.

Singular expressions include plural expressions unless the context clearly dictates otherwise. In addition, when a certain component is said to “include”, this means that it may further include other components without excluding other components unless otherwise stated.

In addition, terms such as “unit” or “part” described in the specification mean a unit that processes at least one function or operation.

In this specification, ‘first circuit’ may refer to a single circuit or a plurality of circuits. In this specification, ‘second circuit’ may refer to a single circuit or a plurality of circuits.

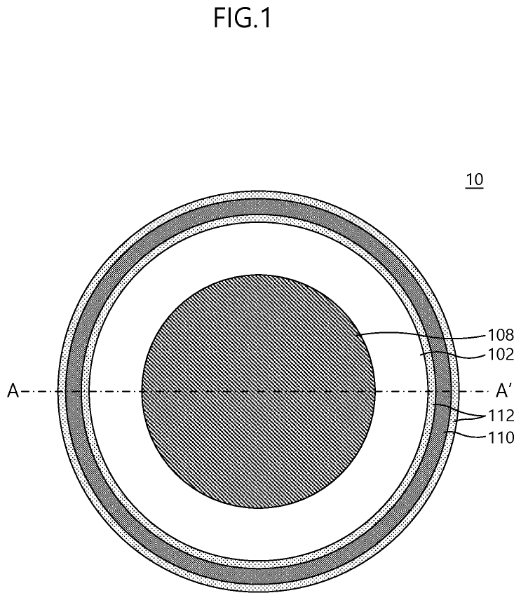

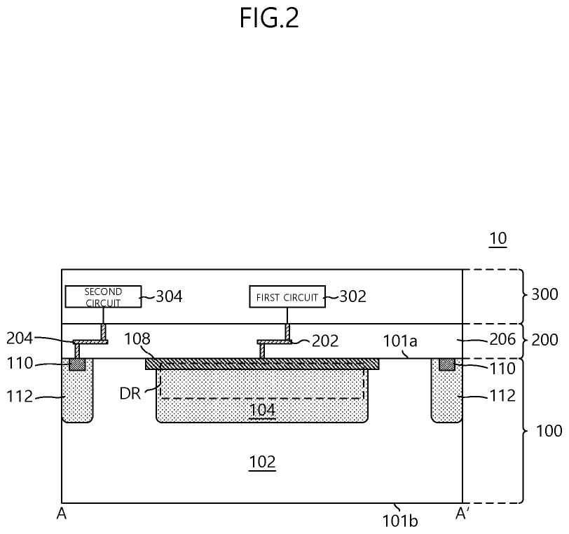

FIG. 1 is a plan view of an avalanche photo detecting element according to an exemplary embodiment. FIG. 2 is a cross-sectional view of the avalanche photo detecting element of FIG. 1 taken along line A-A′.

Referring to FIGS. 1 and 2, An avalanche photodetection device 10 may be provided. The avalanche photodetection device 10 may include a photodetection layer 100, a connection layer 200, and a control layer 300. The photodetection layer 100 may include a front surface 101a and a rear surface 101b facing in opposite directions. The connection layer 200 and the control layer 300 may be stacked on the front surface 101a of the photodetection layer 100. Light may be incident into the photodetection layer 100 through the rear surface 101b of the photodetection layer 100. The avalanche photodetection device 10 may be a back-side illumination (BSI) type image sensor.

The photodetection layer 100 may include an avalanche photodiode (APD) or a single photon avalanche diode (SPAD). A single photon avalanche diode (SPAD) may be referred to as a Geiger-mode avalanche photodiode (G-APD). The photodetection layer 100 may include a substrate region 102, a first well 104, a heavily doped region 108, an anode contact 110, and a relief region 112. The first well 104, the heavily doped region 108, the anode contact 110, and the relief region 112 may be formed by implanting impurities into a semiconductor substrate (eg, a silicon (Si) substrate). The substrate region 102 may be a remaining portion of the semiconductor substrate except for the first well 104, the heavily doped region 108, the anode contact 110, and the relief region 112.

The substrate region 102 may include silicon (Si), germanium (Ge), or silicon germanium (SiGe). The conductivity type of the substrate region 102 may be n-type or p-type. When the conductivity type of the substrate region 102 is n-type, the substrate region 102 may include a group 5 element (eg, phosphorus (P), arsenic (As), antimony (Sb), etc.), group 6 or group 7 element as an impurity. Hereinafter, a region having an n-type conductivity may include a group 5, 6, or 7 element as an impurity. When the conductivity type of the substrate region 102 is p-type, the substrate region 102 may include a group 3 element (eg, boron (B), aluminum (Al), gallium (Ga), indium (In), etc.) or 2 Group elements as impurities. Hereinafter, a region having a p-type conductivity may include a group 3 or group 2 element as an impurity. For example, the doping concentration of the substrate region 102 may be 1×10¹⁴ to 1×10¹⁹ cm⁻³. The semiconductor substrate may be an epi layer formed by an epitaxial growth process.

A first well 104 may be provided on the substrate region 102. The first well 104 may be surrounded by the substrate region 102. The top and bottom surfaces of the first well 104 may be covered by the substrate region 102. The first well 104 may directly contact the substrate region 102. The conductivity type of the first well 104 may be p-type. For example, the doping concentration of the first well 104 may be 1×10¹⁵ to 1×10¹⁸ cm⁻³.

The heavily doped region 108 may be configured to form a depletion region DR. A heavily doped region 108 may be provided on the first well 104. The heavily doped region 108 may contact the first well 104. A width of the heavily doped region 108 may be greater than that of the first well 104. An end portion of the heavily doped region 108 may protrude from a side surface of the first well 104. For example, the central axis of the heavily doped region 108 may be aligned with the central axis of the first well 104. A conductivity type of the heavily doped region 108 may be n-type. For example, the doping concentration of the heavily doped region 108 may be 1×10¹⁵ to 1×10²² cm⁻³. The heavily doped region 108 may be configured such that a positive bias is applied. For example, the first circuit 302 electrically connected to the heavily doped region 108 may include at least one of a DC-to-DC converter, a charge pump, a boost converter, and a power management integrated circuit. In one example, the first circuit 302 may be electrically connected to an external power source. In one example, a contact for a cathode may be additionally provided on one side of the heavily doped region 108.

The depletion region DR may be formed in a region adjacent to an interface between the first well 104 and the heavily doped region 108. When a reverse bias is applied to the photodetection layer 100, a strong electric field may be formed in the depletion region DR. For example, when the photodetection layer 100 operates as a single photon avalanche diode (SPAD), the maximum magnitude of the electric field may be about 1×10⁵ to 1×10⁶ V/cm. Since electrons may be multiplied by the electric field in the depletion region DR, the depletion region DR may be referred to as a multiplication region.

The anode contact 110 may be configured to be electrically connected to a second circuit 304 to be described below. Although the anode contact 110 is shown surrounding the heavily doped region 108, this is exemplary. In another example, a plurality of anode contacts 110 may be provided around the heavily doped region 108. The plurality of anode contacts 110 may be electrically connected to the second circuit 304. The conductivity type of the anode contact 110 may be p-type. A doping concentration of the anode contact 110 may be higher than that of the first well 104. For example, the doping concentration of the anode contact 110 may be 1×10¹⁵ to 1×10²² cm⁻³. When the photodetection layer 100 is a single photon avalanche diode (SPAD), the second circuit 304 may be electrically connected to at least one of a quenching resistor (or quenching circuit) and a pixel circuit. A quench resistor or quenching circuit can stop the avalanche effect and allow the single photon avalanche diode (SPAD) to detect another photon. The pixel circuit may include, for example, a reset or recharge circuit, a memory, an amplifier circuit, a counter, a gate circuit, a time-to-digital converter, and the like. The pixel circuit may receive a signal from the photodetection layer 100.

The relief region 112 may be configured to relieve a difference in doping concentration between the anode contact 110 and the substrate region 102. A relief region 112 may be provided between the anode contact 110 and the first well 104. The relief region 112 may be electrically connected to the anode contact 110 and the first well 104. The relief region 112 may improve electrical connection characteristics between the anode contact 110 and the substrate region 102. For example, the relief region 112 may be configured to reduce or prevent a voltage drop when voltage is applied to the substrate region 102 through the anode contact 110 and to ensure that the voltage is applied to the substrate region 102 uniformly. The relief region 112 may extend along the anode contact 110. The relief region 112 may be provided on side and bottom surfaces of the anode contact 110. For example, the relief region 112 may directly contact the side and bottom surfaces of the anode contact 110. However, the relative position of the relief region 112 with respect to the anode contact 110 may be determined as needed. In another example, the relief region 112 may be provided only on the bottom surface of the anode contact 110 and may not be provided on the side surface of the anode contact 110. The substrate region 102 may extend between the relief region 112 and the heavily doped region 108 and between the relief region 112 and the first well 104. For example, regions between the relief region 112 and the heavily doped region 108 and between the relief region 112 and the first well 104 may be filled with the substrate region 102. The conductivity type of the relief region 112 may be p-type. The doping concentration of the relief region 112 is lower than that of the anode contact 110 and may be similar to or higher than the doping concentration of the substrate region 102. For example, the doping concentration of the relief region 112 may be 1×10¹⁵ to 1×10¹⁹ cm⁻³.

The connection layer 200 may be provided between the photodetection layer 100 and the control layer 300. The connection layer 200 may include the first conductive line 202 configured to electrically connect the heavily doped region 108 and the first circuit 302, a second conductive line 204 configured to electrically connect the anode contact 110 and the second circuit 304, and an insulating layer 206. The first conductive line 202 and the second conductive line 204 may be inserted into the insulating layer 206. The first conductive line 202 and the second conductive line 204 may include an electrically conductive material. For example, the first and second conductive lines 202 and 204 may include copper (Cu), aluminum (Al), tungsten (W), titanium (Ti), titanium nitride (TiN), or a combination thereof. The first and second conductive lines 202 and 204 may include a plurality of portions extending in a direction crossing the front surface 101a of the photodetection layer 100 or in a direction horizontal to the front surface 101a. A positive bias may be applied from the first circuit 302 to the heavily doped region 108 through the first conductive line 202. A signal current may be output from the anode contact 110 to the second circuit 304 through the second conductive line 204. The insulating layer 206 may include an electrically insulating material. For example, insulating layer 206 may include silicon oxide (eg, SiO₂), silicon nitride (eg, SiN), silicon oxynitride (eg, SiON), or combinations thereof.

The control layer 300 may include a first circuit 302 and a second circuit 304 that control the photodetection layer 100. For example, the control layer 300 may be a chip on which the first circuit 302 and the second circuit 304 are formed. Although the first circuit 302 and the second circuit 304 are each shown as one block, this does not mean that each of the first circuit 302 and the second circuit 304 consist of a single electronic element or a circuit having a single function. The first circuit 302 and/or the second circuit 304 may include a plurality of electronic elements and circuits having a plurality of functions as needed. The first circuit 302 may include at least one of a DC-to-DC converter, a charge pump, a boost converter, and a power management integrated circuit. The first circuit 302 may be configured to be electrically connected to an external power source. When the photodetection layer 100 includes a single photon avalanche diode (SPAD), the second circuit 304 is a quenching resistor (or quenching circuit) and a pixel circuit can include A quenching resistor or quenching circuit can be configured to stop the avalanche effect and allow the single photon avalanche diode (SPAD) to detect another photon. The pixel circuit may include, for example, a reset or recharge circuit, a memory, an amplifier circuit, a counter, a gate circuit, a time-to-digital converter, and the like. The pixel circuit may transmit a signal to the photodetection layer 100 or receive a signal from the photodetection layer 100.

When the control layer 300 and the photodetection layer 100 are formed on the same semiconductor substrate, a semiconductor device (eg, an inverter) included in the control layer 300 may be formed on the substrate region 102. In order to drive a semiconductor device (eg, an inverter) included in the control layer 300, a ground voltage should be applied to the substrate region 102. When the ground voltage is applied to the substrate region 102, the ground voltage is also applied to the anode (first well 104) contacting the substrate region 102. Therefore, the cathode (highly doped region) is biased, and the signal is also output from the cathode (heavily doped region). In some example embodiments, the voltage applied to the cathode has a magnitude that the transistor cannot withstand. For example, the magnitude of the voltage is 10 volts (V) to 20 volts (V). In general, the quenching circuit may have a simple or complex configuration. However, when the magnitude of the voltage is so large that the transistor cannot withstand it, it is difficult for the quenching circuit to have a simple configuration (for example, a configuration using a transistor that directly receives a signal). That is, when the magnitude of the voltage is so large that the transistor cannot withstand it, the quenching circuit has a complicated configuration (for example, a configuration using additional elements such as a polysilicon resistor and a coupling capacitor). As a result, when the control layer 300 and the photodetection layer 100 are formed on the same semiconductor substrate, the circuit configuration of the avalanche photodetection device 10 may be complicated and its size may be large.

Avalanche photo detecting element having the same configuration as the avalanche photodetection device 10 of the present disclosure, but configured such that the anode (first well 104) is biased and a signal is output from the cathode (highly-doped region 108) uses a negative bias. Since most semiconductor devices require a positive bias, a system including an avalanche photodetection device with a bias applied to the anode and other semiconductor devices should have both of a power supply with a positive bias and a power supply with a negative bias. Therefore, the system may be complex and large in size. In addition, the pixel circuit may become complicated or inefficient, such as the use of PMOS being increased.

Since the control layer 300 and the photodetection layer 100 of the present disclosure are not formed on the same semiconductor substrate, the substrate region 102 does not need to be applied with a ground voltage. Also, the cathode (heavily doped region 108) is biased with a positive bias, and a signal is output from the anode (first well 104). Since the conductive line on which biasing is performed and the conductive line on which signals are output are electrically separated and no bias is applied to the quenching circuit, the quenching circuit can have a simple configuration. A system including semiconductor devices other than the avalanche photodetection device 10 of the present disclosure may require only a power supply for supplying a positive bias without a power supply for supplying a negative bias. Accordingly, a simple and miniaturized semiconductor system can be provided. Also, a three-dimensional avalanche photodetection device using a simple and efficient pixel circuit can be provided.

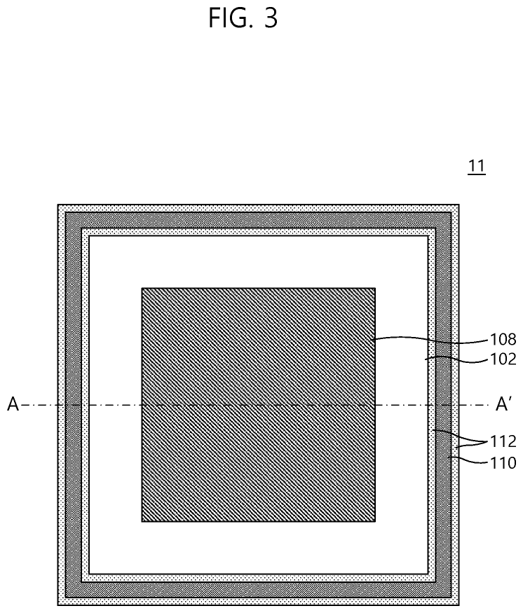

FIG. 3 is a plan view of the avalanche photodetection device of FIG. 2 according to an exemplary embodiment. Differences from those shown in FIG. 1 are described for brevity of explanation.

Referring to FIG. 3, an avalanche photodetection device 11 may be provided. Unlike that shown in FIG. 1, the avalanche photodetection device 11 may have a square shape. Specifically, the heavily doped region 108 may have a square shape, and the substrate region 102, the relief region 112, and the anode contact 110 may have a square ring shape surrounding the heavily doped region 108. For example, the heavily doped region 108, the substrate region 102, the relief region 112, and the anode contact 110 may have the same center.

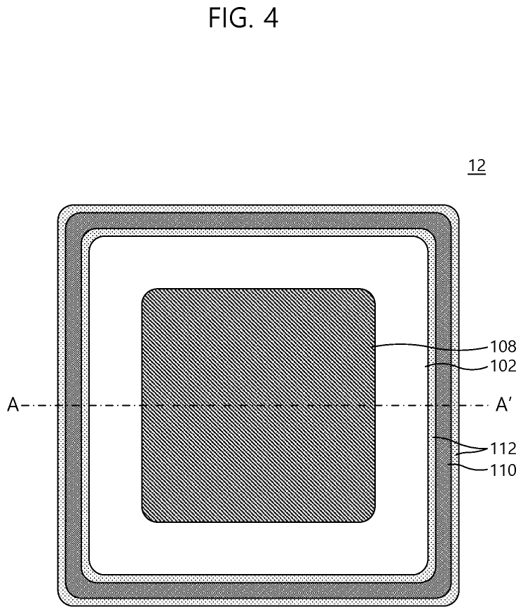

FIG. 4 is a plan view of the avalanche photodetection device of FIG. 2 according to an exemplary embodiment. Differences from those shown in FIG. 1 are described for brevity of explanation.

Referring to FIG. 4, an avalanche photodetection device 12 may be provided. Unlike that shown in FIG. 1, the avalanche photodetection device 12 may have a square shape with rounded corners. Specifically, the heavily doped region 108 may have a square shape with rounded corners, and the substrate region 102, the relief region 112, and the anode contact 110 may have a square ring shape with rounded corners surrounding the heavily doped region 108. For example, the heavily doped region 108, the substrate region 102, the relief region 112, and the anode contact 110 may have the same center.

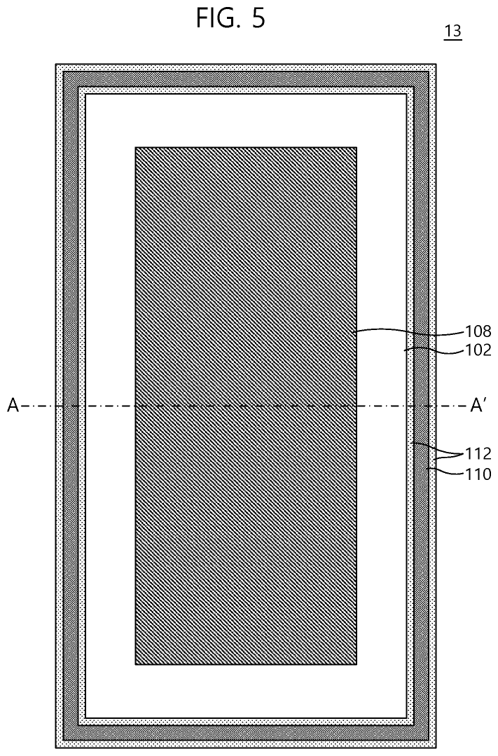

FIG. 5 is a plan view of the avalanche photodetection device of FIG. 2 according to an exemplary embodiment. Differences from those shown in FIG. 1 are described for brevity of explanation.

Referring to FIG. 5, an avalanche photodetection device 13 may be provided. Unlike that shown in FIG. 1, the avalanche photodetection device 13 may have a rectangular shape. Specifically, the heavily doped region 108 may have a rectangular shape, and the substrate region 102, the relief region 112, and the anode contact 110 may have a rectangular ring shape surrounding the heavily doped region 108. For example, the heavily doped region 108, the substrate region 102, the relief region 112, and the anode contact 110 may have the same center.

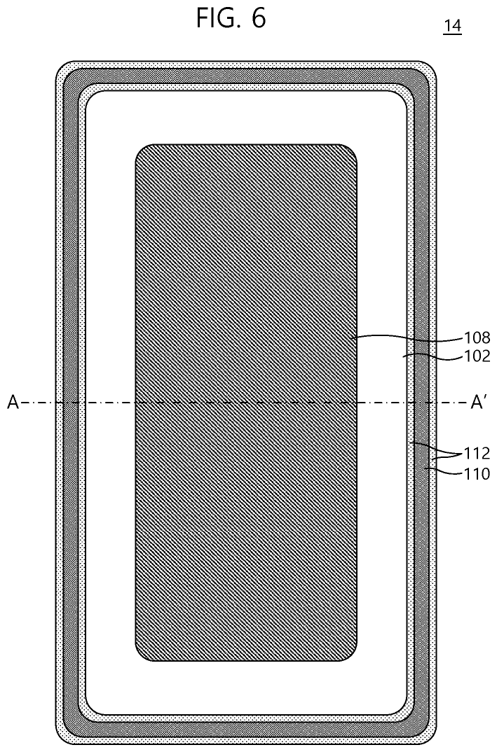

FIG. 6 is a plan view of the avalanche photodetection device of FIG. 2 according to an exemplary embodiment. Differences from those shown in FIG. 1 are described for brevity of explanation.

Referring to FIG. 6, an avalanche photodetection device 14 may be provided. Unlike that shown in FIG. 1, the avalanche photodetection device 14 may have a rectangular shape with rounded corners. Specifically, the heavily doped region 108 may have a rectangular shape with rounded corners, and the substrate region 102, the relief region 112, and the anode contact 110 may have a rounded rectangular ring shape with rounded corners surrounding the heavily doped region 108. For example, the heavily doped region 108, the substrate region 102, the relief region 112, and the anode contact 110 may have the same center.

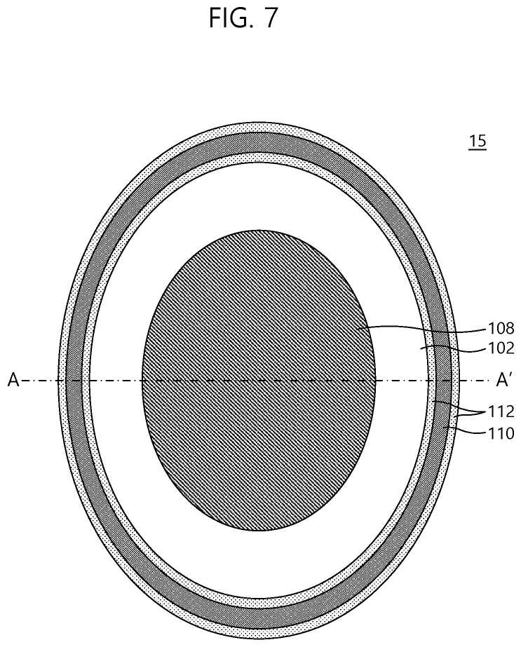

FIG. 7 is a plan view of the avalanche photodetection device of FIG. 2 according to an exemplary embodiment. Differences from those shown in FIG. 1 are described for brevity of explanation.

Referring to FIG. 7, an avalanche photodetection device 15 may be provided. Unlike that shown in FIG. 1, the avalanche photodetection device 15 may have an elliptical shape. Specifically, the heavily doped region 108 may have an elliptical shape, and the substrate region 102, the relief region 112, and the anode contact 110 may have an elliptical ring shape surrounding the heavily doped region 108. For example, the heavily doped region 108, the substrate region 102, the relief region 112, and the anode contact 110 may have the same center.

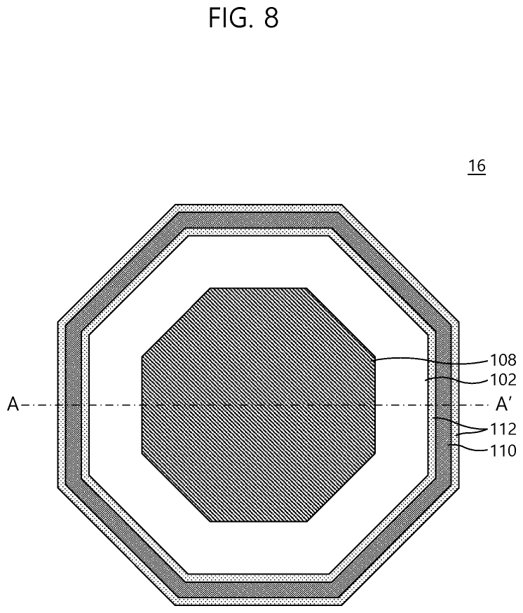

FIG. 8 is a plan view of the avalanche photodetection device of FIG. 2 according to an exemplary embodiment. Differences from those shown in FIG. 1 are described for brevity of explanation.

Referring to FIG. 8, an avalanche photodetection device 16 may be provided. Unlike that shown in FIG. 1, the avalanche photodetection device 16 may have an octagonal shape. Specifically, the heavily doped region 108 may have an octagonal shape, and the substrate region 102, the relief region 112, and the anode contact 110 may have an octagonal ring shape surrounding the heavily doped region 108. For example, the heavily doped region 108, the substrate region 102, the relief region 112, and the anode contact 110 may have the same center.

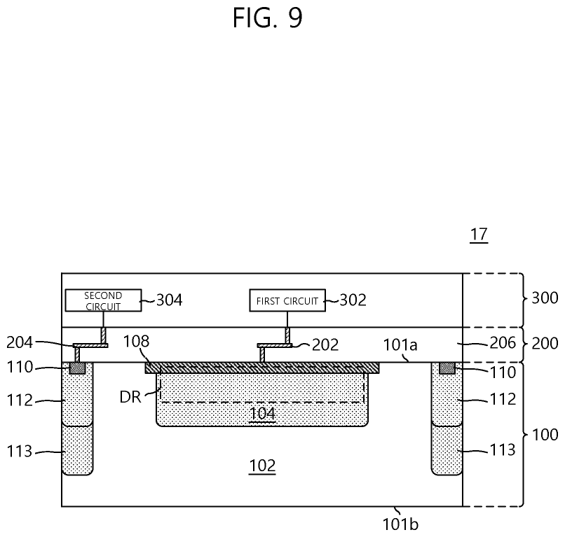

FIG. 9 is a cross-sectional view corresponding to line A-A′ of the avalanche photodetection device of FIG. 1. Differences from those described with reference to FIGS. 1 and 2 are described for brevity of description.

Referring to FIG. 9, an avalanche photodetection device 17 may be provided. Unlike the description with reference to FIGS. 1 and 2, the avalanche photodetection device 17 may further include an additional relief region 113. An additional relief region 113 may be provided on the bottom surface of the relief region 112. The additional relief region 113 may be formed to a position deeper than the first well 104. The bottom surface of the additional relief region 113 may be disposed closer to the rear surface 101b of the photodetection layer 100 than the bottom surface of the first well 104. The side of the additional relief region 113 may be aligned with the side of the relief region 112. The side surface of the additional relief region 113 and the side surface of the relief region 112 may be coplanar. The conductivity type of the additional relief region 113 may be p-type. For example, the doping concentration of the additional relief region 113 may be 1×10¹⁵ to 1×10¹⁸ cm⁻³. The additional relief region 113 may improve electrical connection characteristics between the anode contact 110 and the substrate region 102. For example, the additional relief region 113 is configured to reduce or prevent a voltage drop when voltage is applied to the substrate region 102 through the anode contact 110 and to ensure that the voltage is applied to the substrate region 102 uniformly.

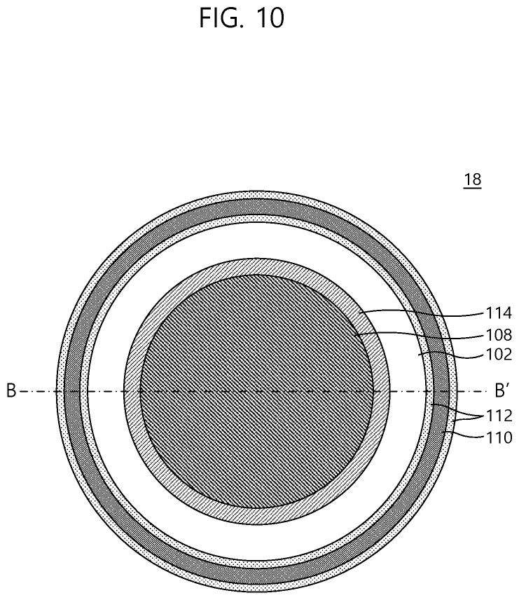

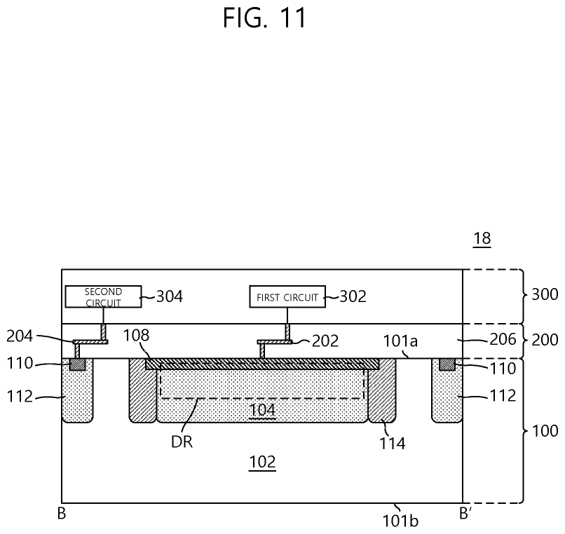

FIG. 10 is a plan view of an avalanche photodetection device according to an exemplary embodiment. FIG. 11 is a cross-sectional view of the avalanche photodetection device of FIG. 10 taken along line B-B′. Differences from those described with reference to FIGS. 1 and 2 are described for brevity of description.

Referring to FIGS. 10 and 11, an avalanche photodetection device 18 may be provided. Unlike the description with reference to FIGS. 1 and 2, the avalanche photodetection device 18 may further include a guard ring 114. The guard ring 114 may be provided on a side surface of the heavily doped region 108 and a side surface of the first well 104. The guard ring 114 may extend from a region on the side surface of the heavily doped region 108 to a region on the side surface of the first well 104. The guard ring 114 may surround the heavily doped region 108 and the first well 104. For example, the guard ring 114 may have a ring shape extending along the side surfaces of the heavily doped region 108 and the side surfaces of the first well 104. The guard ring 114 may directly contact the heavily doped region 108 and the first well 104. In another example, the guard ring 114 may be apart from the heavily doped region 108 and the first well 104. The top surface of the guard ring 114 and the top surface of the heavily doped region 108 may be disposed at substantially the same height. The bottom surface of the guard ring 114 may be disposed at substantially the same height as the bottom surface of the first well 104. The conductivity type of the guard ring 114 may be n-type. The doping concentration of the guard ring 114 may be lower than that of the heavily doped region 108. For example, the doping concentration of the guard ring 114 may be 1×10¹⁵ to 1×10¹⁸ cm⁻³.

The guard ring 114 may be configured to reduce or prevent generation of noise and after pulses by blocking electrons or holes generated by defects in the semiconductor substrate from moving to the multiplication region. Furthermore, the guard ring 114 may be configured to reduce or prevent an early breakdown phenomenon by relieving the concentration of an electric field at the edge of the heavily doped region 108.

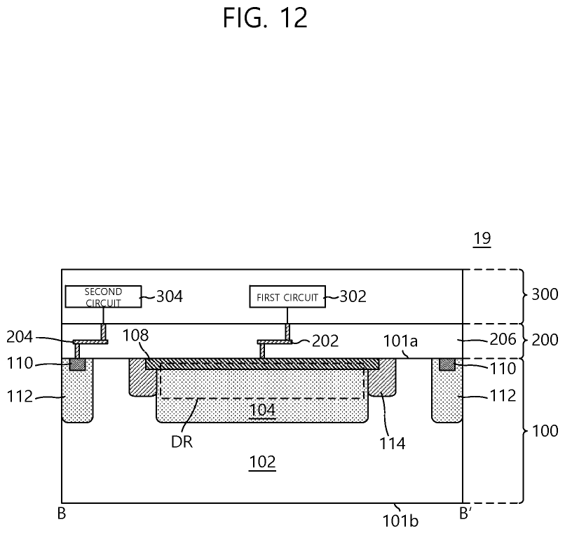

FIG. 12 is a cross-sectional view corresponding to line B-B′ of the avalanche photodetection device of FIG. 10. Differences from those described with reference to FIGS. 10 and 11 are described for brevity of description.

Referring to FIG. 12, an avalanche photodetection device 19 may be provided. Unlike the description with reference to FIGS. 10 and 11, the bottom surface of the guard ring 114 may be disposed at a height between the bottom surface and the top surface of the first well 104. The guard ring 114 may be formed to a shallower depth than the first well 104. The guard ring 114 may be configured to reduce or prevent noise generation due to defects in the semiconductor substrate. The doping concentration of the guard ring 114 may be higher than that of the guard ring 114 described with reference to FIGS. 10 and 11. For example, the doping concentration of the guard ring 114 may be 1×10¹⁶ to 1×10¹⁸ cm⁻³.

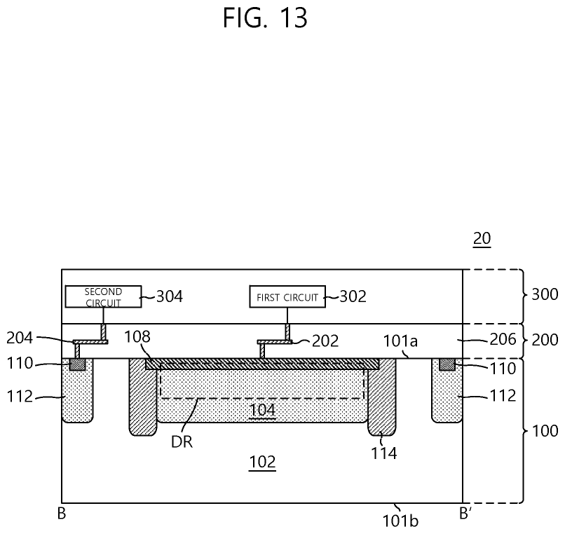

FIG. 13 is a cross-sectional view corresponding to line B-B′ of the avalanche photodetection device of FIG. 10. Differences from those described with reference to FIGS. 10 and 11 are described for brevity of description.

Referring to FIG. 13, an avalanche photodetection device 20 may be provided. Unlike the description with reference to FIGS. 10 and 11, the bottom surface of the first well 104 may be disposed at a height between the bottom surface and the top surface of the guard ring 114. The guard ring 114 may be formed to a depth greater than that of the first well 104. The guard ring 114 may be configured to reduce or prevent noise generation due to defects in the semiconductor substrate. The doping concentration of the guard ring 114 may be lower than that of the guard ring 114 described with reference to FIGS. 10 and 11. For example, the doping concentration of the guard ring 114 may be 1×10¹⁵ to 1×10¹⁷ cm⁻³.

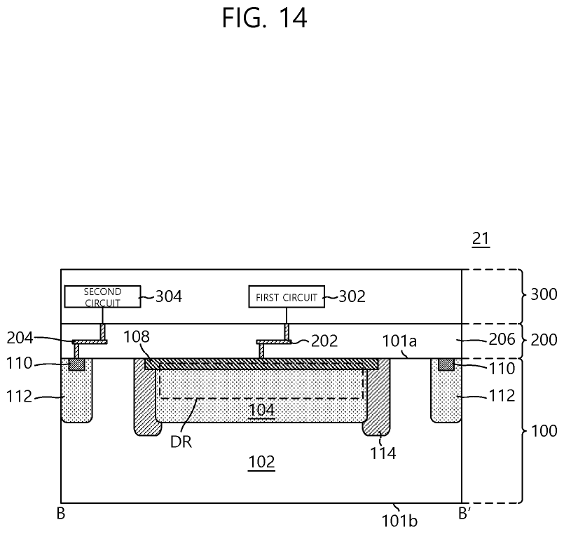

FIG. 14 is a cross-sectional view corresponding to line B-B′ of the avalanche photodetection device of FIG. 10. Differences from those described with reference to FIGS. 10 and 11 are described for brevity of description.

Referring to FIG. 14, an avalanche photodetection device 21 may be provided. Unlike those described with reference to FIGS. 10 and 11, the guard ring 114 may extend from a region on the side surface of the first well 104 to a region on the bottom surface of the first well 104. The guard ring 114 may be formed to a depth greater than that of the first well 104. The guard ring 114 may be configured to reduce or prevent noise generation due to defects in the semiconductor substrate. For example, the doping concentration of the guard ring 114 may be 1×10¹⁵ to 1×10¹⁸ cm⁻³.

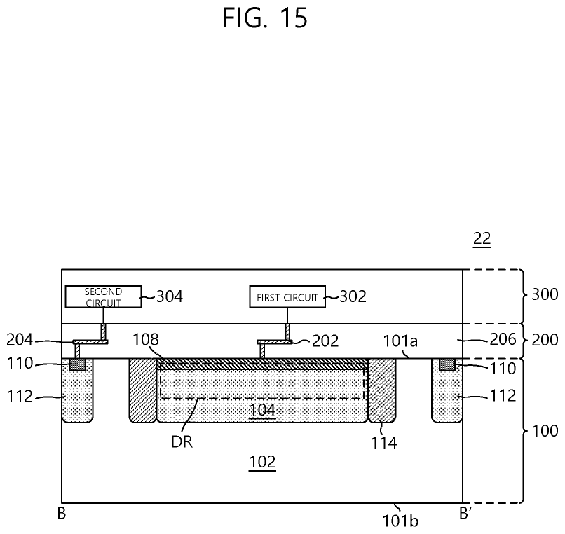

FIG. 15 is a cross-sectional view corresponding to line B-B′ of the avalanche photodetection device of FIG. 10. Differences from those described with reference to FIGS. 10 and 11 are described for brevity of description.

Referring to FIG. 15, an avalanche photodetection device 22 may be provided. Unlike the description with reference to FIGS. 10 and 11, a side surface of the heavily doped region 108 may be aligned with a side surface of the first well 104. The side surface of the heavily doped region 108 may be coplanar with the side surface of the first well 104. An end portion of the heavily doped region 108 may not protrude from a side surface of the first well 104.

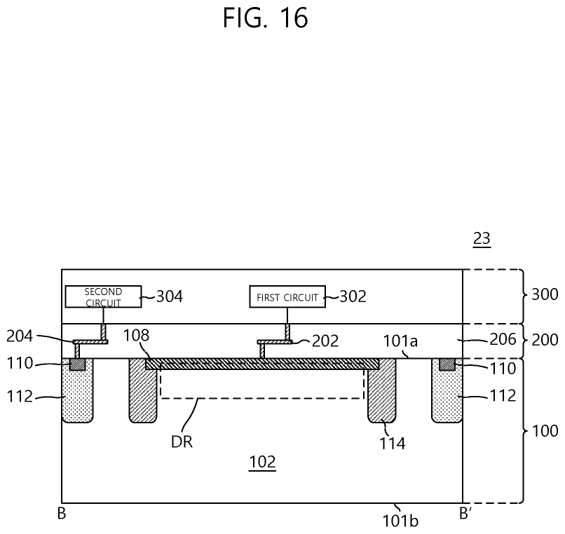

FIG. 16 is a cross-sectional view corresponding to line B-B′ of the avalanche photodetection device of FIG. 10. Differences from those described with reference to FIGS. 10 and 11 are described for brevity of description.

Referring to FIG. 16, an avalanche photodetection device 23 may be provided. Unlike the description with reference to FIGS. 10 and 11, the first well 104 may not be provided. The heavily doped region 108 may directly contact with the substrate region 102. The depletion region DR may be formed in a region adjacent to an interface between the heavily doped region 108 and the substrate region 102.

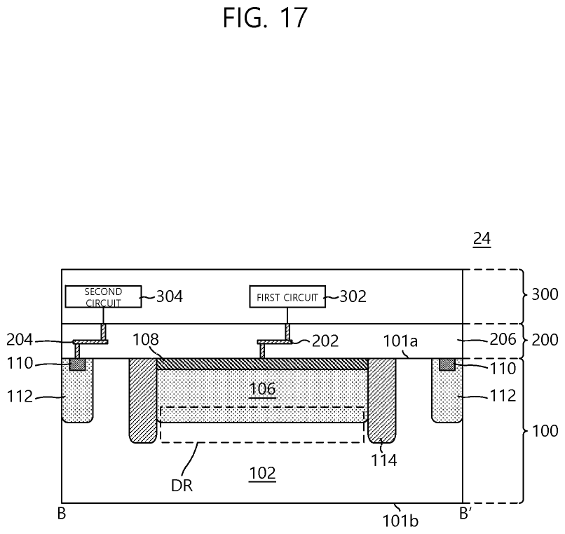

FIG. 17 is a cross-sectional view corresponding to line B-B′ of the avalanche photodetection device of FIG. 10. Differences from those described with reference to FIG. 16 are described for brevity of description.

Referring to FIG. 17, an avalanche photodetection device 24 may be provided. Unlike the description with reference to FIG. 16, the second well 106 may be provided between the substrate region 102 and the heavily doped region 108. The first well 104 may not be provided. The heavily doped region 108 and the substrate region 102 is apart from each other by the second well 106. The second well 106 may be provided on the bottom surface of the heavily doped region 108. A side surface of the second well 106 and a side surface of the heavily doped region 108 may be aligned. The side surface of the second well 106 and the side surface of the heavily doped region 108 may be coplanar. The conductivity type of the second well 106 may be n-type. The doping concentration of the second well 106 may be lower than that of the heavily doped region 108 and higher than that of the guard ring 114. For example, the doping concentration of the second well 106 may be 1×10¹⁶ to 1×10¹⁸ cm⁻³. The depletion region DR may be formed adjacent to an interface between the second well 106 and the substrate region 102.

The guard ring 114 may extend from the front surface 101a of the photodetection layer 100 to a position deeper than the bottom surface of the second well 106. For example, the bottom surface of the guard ring 114 may be disposed closer to the rear surface 101b of the photodetection layer 100 than the bottom surface of the second well 106. The guard ring 114 may be configured to reduce or prevent noise generation due to defects in the semiconductor substrate. The guard ring 114 may have a lower doping concentration than the second well 106. For example, the doping concentration of the guard ring 114 may be 1×10¹⁵ to 1×10¹⁷ cm⁻³.

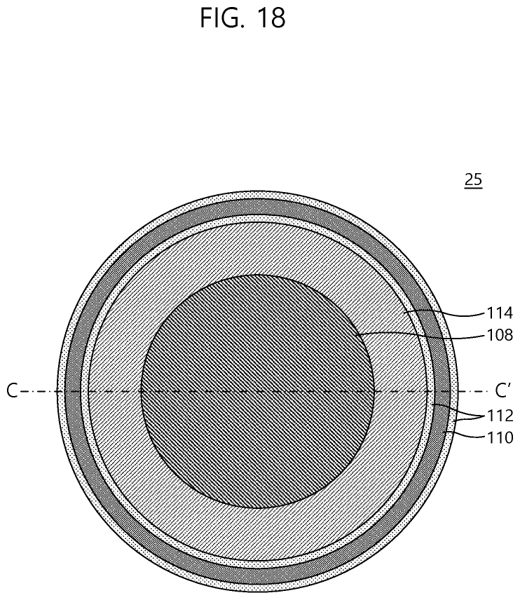

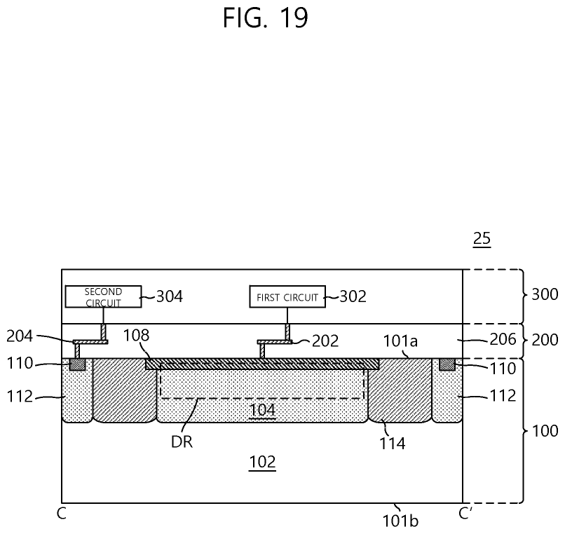

FIG. 18 is a plan view of an avalanche photodetection device according to an exemplary embodiment. FIG. 19 is a cross-sectional view of the avalanche photodetection device of FIG. 18 taken along line C-C′. Differences from those described with reference to FIGS. 10 and 11 are described for brevity of description.

Referring to FIGS. 18 and 19, an avalanche photodetection device 25 may be provided. Unlike the description with reference to FIGS. 10 and 11, the guard ring 114 may directly contact the first well 104, the heavily doped region 108, and the relief region 112. For example, the guard ring 114 may fill a region between the relief region 112 and the first well 104 and a region between the relief region 112 and the heavily doped region 108. As shown in FIG. 12, when the bottom surface of the guard ring 114 is positioned at a height between the top surface and the bottom surface of the first well 104, the guard ring 114 may fill a portion of the region between the relief region 112 and the first well 104, and the substrate region 102 may fill another portion of the region between the relief region 112 and the first well 104.

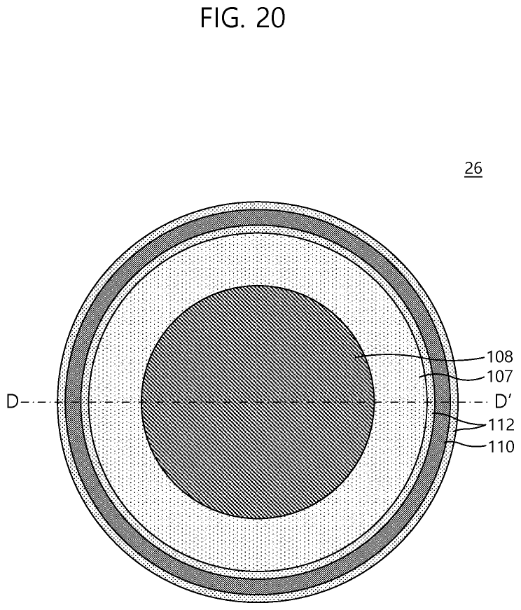

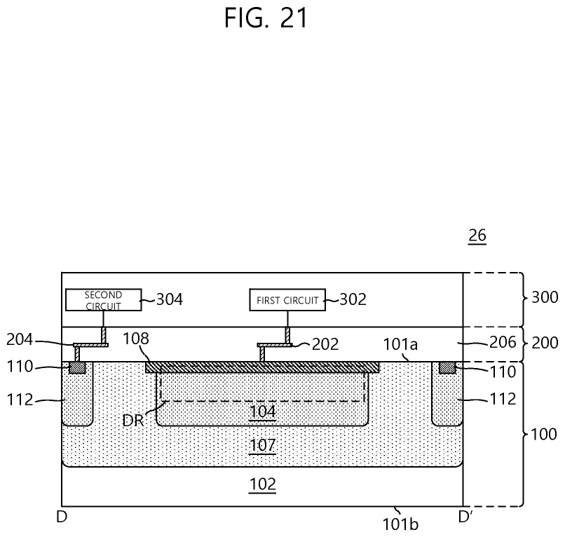

FIG. 20 is a plan view of an avalanche photodetection device according to an exemplary embodiment. FIG. 21 is a cross-sectional view of the avalanche photodetection device of FIG. 20 taken along line D-D′. Differences from those described with reference to FIGS. 1 and 2 are described for brevity of description.

Referring to FIGS. 20 and 21, an avalanche photodetection device 26 may be provided. Unlike the description with reference to FIGS. 1 and 2, a third well 107 may be provided between the first well 104 and the substrate region 102. The third well 107 may extend to a region between the first well 104 and the relief region 112 and to a region between the heavily doped region 108 and the relief region 112. The third well 107 may directly contact the substrate region 102. The conductivity type of the third well 107 may be p-type. The doping concentration of the third well 107 may be higher than that of the substrate region 102. For example, the doping concentration of the third well 107 may be 1×10¹⁵ to 1×10¹⁹ cm⁻³. In one example, the doping concentration of the third well 107 may decrease as it is closer to the front surface 101a of the photodetection layer 100. In one example, the third well 107 may have a uniform doping concentration.

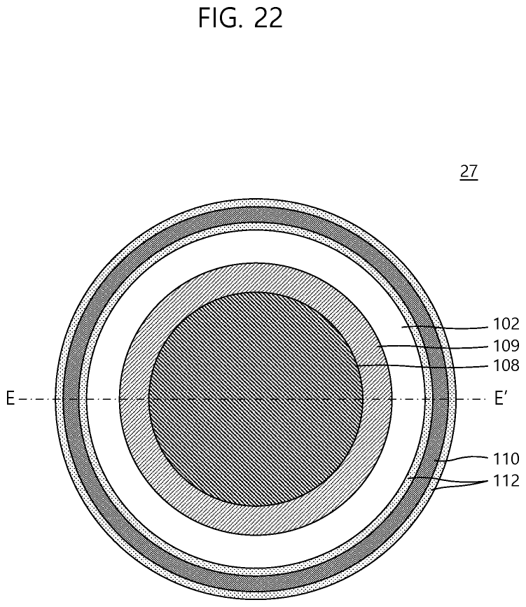

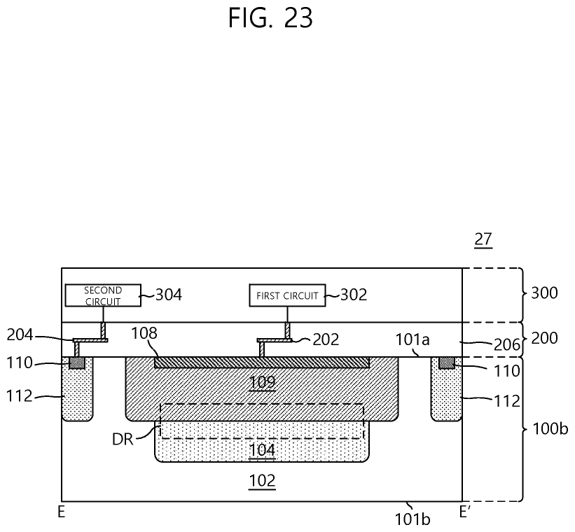

FIG. 22 is a plan view of an avalanche photodetection device according to an exemplary embodiment. FIG. 23 is a cross-sectional view of the avalanche photodetection device of FIG. 22 taken along line E-E′. For brevity of description, content substantially the same as that described with reference to FIGS. 1 and 2 may not be described.

Referring to FIGS. 22 and 23, an avalanche photodetection device 27 may be provided. Unlike the description with reference to FIGS. 1 and 2, a fourth well 109 may be provided between the first well 104 and the heavily doped region 108. The fourth well 109 may separate the heavily doped region 108 and the first well 104 from each other. The fourth well 109 may extend between the substrate region 102 and the heavily doped region 108. The fourth well 109 may separate the substrate region 102 and the heavily doped region 108 from each other. The conductivity type of the fourth well 109 may be n-type. The doping concentration of the fourth well 109 may be lower than that of the heavily doped region 108. For example, the doping concentration of the fourth well 109 may be 1×10¹⁶ to 1×10¹⁸ cm⁻³. The depletion region DR may be formed in a region adjacent to an interface between the fourth well 109 and the first well 104.

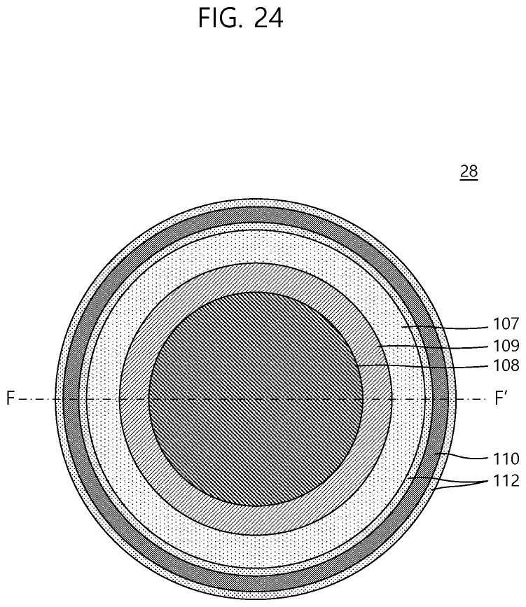

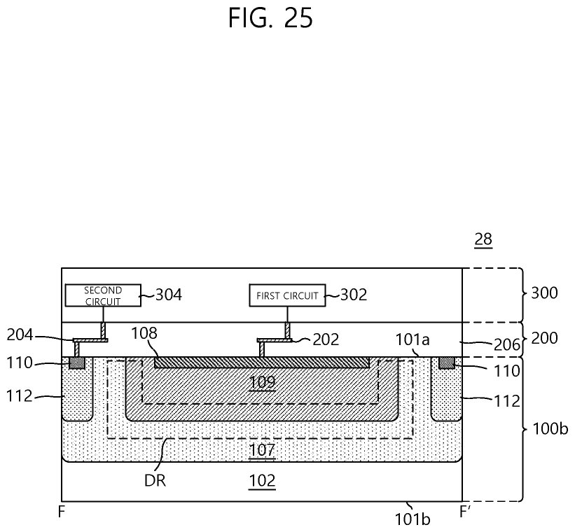

FIG. 24 is a plan view of an avalanche photodetection device according to an exemplary embodiment. FIG. 25 is a cross-sectional view of the avalanche photodetection device of FIG. 24 taken along line F-F′. For brevity of description, differences from those described with reference to FIGS. 22 and 23 are described.

Referring to FIGS. 24 and 25, an avalanche photodetection device 28 may be provided. Unlike the description with reference to FIGS. 22 and 23, a third well 107 may be provided between the fourth well 109 and the substrate region 102. The third well 107 may extend to a region between the fourth well 109 and the relief region 112 and to a region between the heavily doped region 108 and the relief region 112. The third well 107 may directly contact the substrate region 102. The conductivity type of the third well 107 may be p-type. The doping concentration of the third well 107 may be higher than that of the substrate region 102. For example, the doping concentration of the third well 107 may be 1×10¹⁵ to 1×10¹⁹ cm⁻³. In one example, the doping concentration of the third well 107 may decrease as it is closer to the front surface 101a of the photodetection layer 100. In one example, the third well 107 may have a uniform doping concentration. The depletion region DR may be formed along an interface between the third well 107 and the fourth well 109.

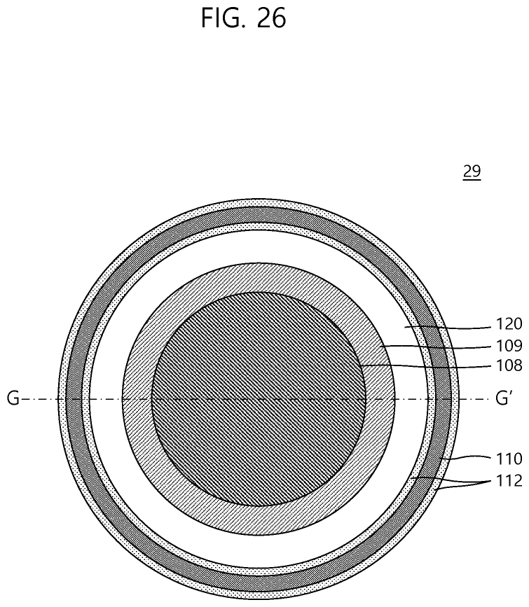

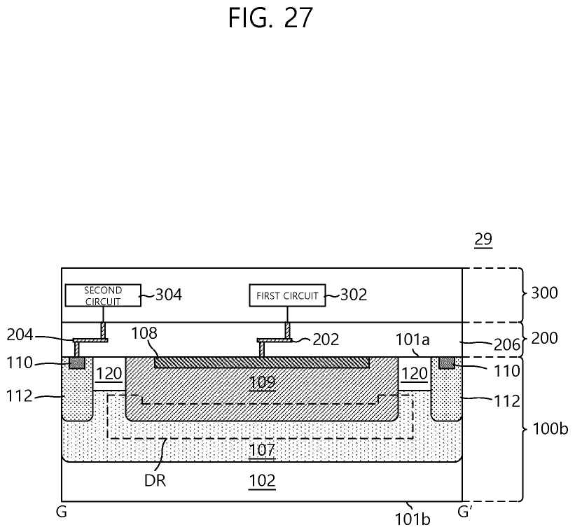

FIG. 26 is a plan view of an avalanche photodetection device according to an exemplary embodiment. FIG. 27 is a cross-sectional view corresponding to the line G-G′ of the avalanche photodetection device of FIG. 26. For brevity of description, differences from those described with reference to FIGS. 24 and 25 are described.

Referring to FIGS. 26 and 27, an avalanche photodetection device 29 may be provided. Unlike the description with reference to FIGS. 24 and 25, the sub-substrate region 120 may be provided between the relief region 112 and the fourth well 109. The sub-substrate region 120 may surround the fourth well 109. The conductivity type of the sub-substrate region 120 may be p-type. The sub-substrate region 120 may have substantially the same doping concentration as the substrate region 102. For example, the doping concentration of the sub-substrate region 120 may be 1×10¹⁴ to 1×10¹⁹ cm⁻³. The sub-substrate region 120 may extend from the front surface 101a of the avalanche photodetection device 29 to a predetermined depth. For example, the rear surface of the sub-substrate region 120 may be located at a height between the top surface and the bottom surface of the fourth well 109. In one example, the sub-substrate region 120 may be a region above the substrate region 102 where ions are not implanted in the ion implantation process of forming the third well 107 (ie, an upper portion of the semiconductor substrate).

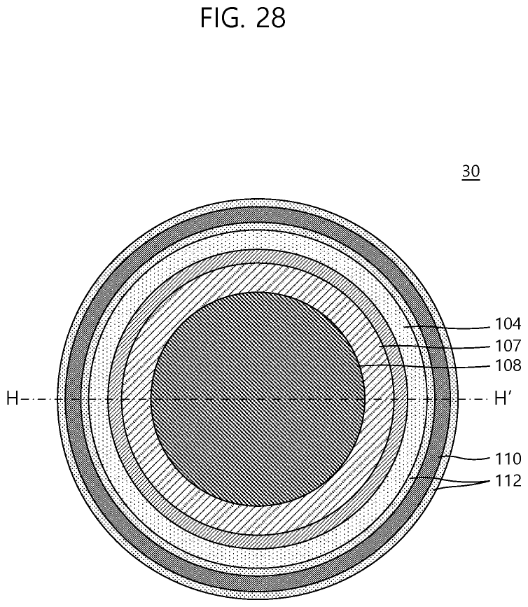

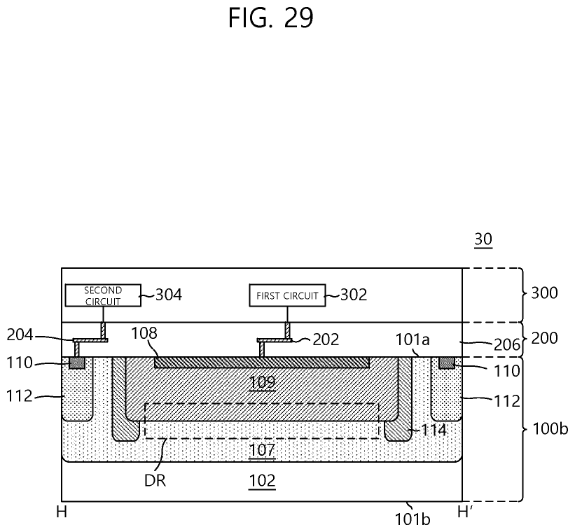

FIG. 28 is a plan view of an avalanche photodetection device according to an exemplary embodiment. FIG. 29 is a cross-sectional view corresponding to line H-H′ of the avalanche photodetection of FIG. 28. For brevity of description, differences from those described with reference to FIGS. 24 and 25 are described.

Referring to FIGS. 28 and 29, an avalanche photodetection device 30 may be provided. Unlike the description with reference to FIGS. 24 and 25, a guard ring 114 may be provided on a side surface of the fourth well 109. The guard ring 114 may extend from a region on the side surface of the fourth well 109 to a region on the bottom surface of the fourth well 109. The bottom surface of the guard ring 114 may be located closer to the bottom surface of the third well 107 than the bottom surface of the fourth well 109. The conductivity type of the guard ring 114 may be n-type. The doping concentration of the guard ring 114 may be lower than that of the fourth well 109. For example, the doping concentration of the guard ring 114 may be 1×10¹⁵ to 1×10¹⁸ cm⁻³.

The guard ring 114 may be configured to reduce or prevent generation of noise and after pulses by blocking electrons or holes generated by defects in the semiconductor substrate from moving to the multiplication region. Furthermore, the guard ring 114 may be configured to reduce or prevent an early breakdown phenomenon by relieve the concentration of the electric field at the edge of the fourth well 109.

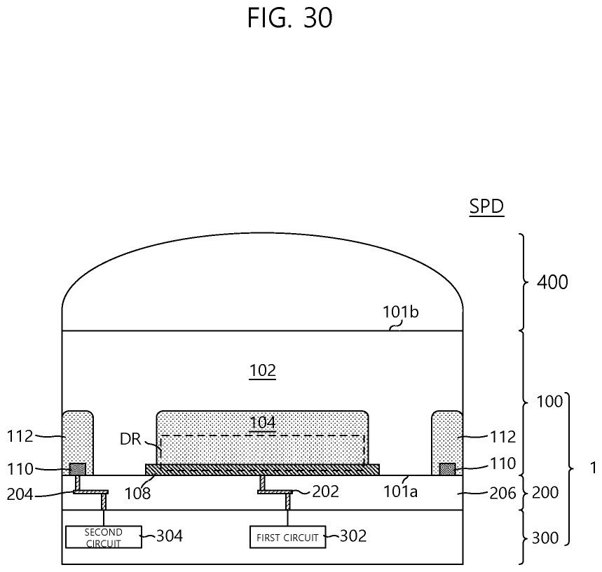

FIG. 30 is a cross-sectional view of an avalanche photodetector according to an exemplary embodiment. For brevity of description, content substantially the same as that described with reference to FIGS. 1 and 2 may not be described.

Referring to FIG. 30, an avalanche photodetector SPD may be provided. The avalanche photodetector SPD may include a photodetection layer 100, a connection layer 200, a control layer 300, and a lens unit 400. The photodetection layer 100, the connection layer 200, and the control layer 300 may be referred to as an avalanche photodetection device 1. The avalanche photodetector SPD may be a back side illumination (BSI) type image sensor. The front side may be a surface on which various semiconductor processes are performed during the manufacture of the photodetection layer 100 (the front surface 101a of the photodetection layer 100), and the back side is a side disposed on the opposite side of the front side (the rear surface 101b of the photodetection layer 100). The back side illumination method may refer to light incident on the rear surface of the photodetection layer 100. A front side illumination method may refer to light incident on the front surface of the photodetection layer 100.

Although the avalanche photodetection device 1 is shown as being substantially the same as the avalanche photodetection device 10 described with reference to FIGS. 1 and 2, this is not limiting. The avalanche photodetection device 1 may be any one of the other avalanche photodetection devices 11 to 30 described above.

The lens unit 400 may be provided on the rear surface 101b of the photodetection layer 100. The lens unit 400 may focus incident light and transmit it to the photodetection layer 100. For example, the lens unit 400 may include a microlens or a Fresnel lens. In one example, the central axis of the lens unit 400 may be aligned with the central axis of the photodetection layer 100. The central axis of the lens unit 400 may be an imaginary axis that passes through the center of the lens unit 400 and is parallel to the stacking direction of the photodetection layer 100 and the lens unit 400. The central axis of the photodetection layer 100 may be an imaginary axis that passes through the center of the photodetector layer 100 and is parallel to the stacking direction of the photodetector layer 100 and the lens unit 400. In one example, the central axis of the lens unit 400 may be misaligned with the central axis of the photodetection layer 100. In one embodiment, at least one optical element may be inserted between the lens unit 400 and the photodetection layer 100. For example, the optical element may be a color filter, a bandpass filter, a metal grid, an anti-reflection coating, a 2D nanomaterial layer, or an organic material layer. In one example, the anti-reflection coating may be formed on the top of the lens unit 400.

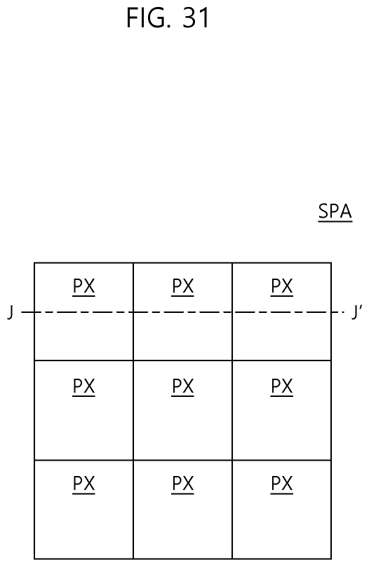

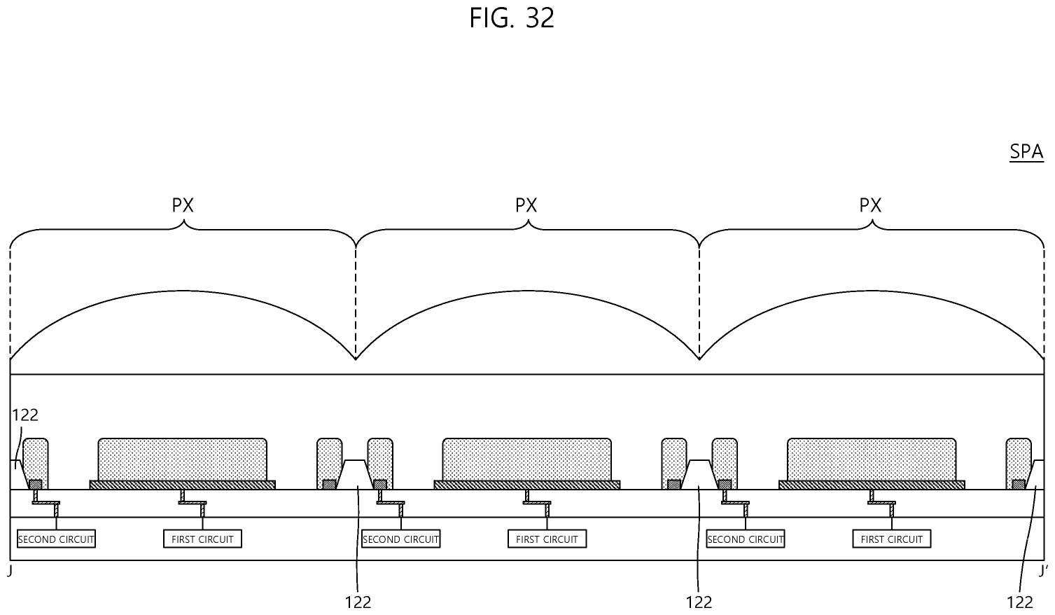

FIG. 31 is a top view of an avalanche photodetector array according to an exemplary embodiment. FIG. 32 is cross-sectional views taken along the line J-J′ of FIG. 31. For brevity of description, content substantially the same as that described with reference to FIG. 30 may not be described.

Referring to FIG. 31, an avalanche photodetector array SPA may be provided. The avalanche photodetector array SPA may include pixels PX arranged in two dimensions. Referring to FIG. 32, each of the pixels PX may include the avalanche photodetector SPD of FIG. 30 described with reference to FIG. 30. Directly adjacent substrate regions 102 in FIG. 30, directly adjacent connection layers 200 in FIG. 30, directly adjacent control layers 300 in FIG. 30, and directly adjacent lens units 400 in FIG. 30 are connected to each other.

An isolation layer 122 may be provided between the pixels PX. The isolation layer 122 can prevent a crosstalk phenomenon in which light incident on a pixel is detected by another pixel adjacent to the pixel. For example, the isolation layer 122 may include silicon oxide, silicon nitride, silicon oxynitride, polycrystalline silicon, a low-k dielectric material, a metal, or a combination thereof. In one example, a metal grid may be provided in a lower region of the lens unit 400 between the pixels PX. For example, the metal grid may include tungsten, copper, aluminum, or combinations thereof.

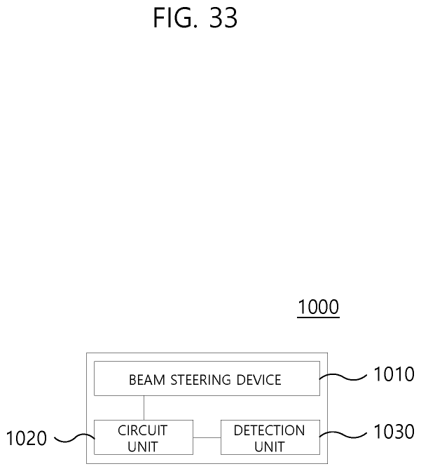

FIG. 33 is a block diagram for describing an electronic device according to an exemplary embodiment.

Referring to FIG. 33, an electronic device 1000 may be provided. The electronic device 1000 may radiate light toward a subject (not shown) and detect light reflected by the subject and returned to the electronic device 1000. The electronic device 1000 may include a beam steering device 1010. The beam steering device 1010 may adjust a direction of irradiation of light emitted to the outside of the electronic device 1000. The beam steering device 1010 may be a mechanical or non-mechanical (semiconductor) beam steering device. The electronic device 1000 may include a light source unit within the beam steering device 1010 or may include a light source unit provided separately from the beam steering device 1010. The beam steering device 1010 may be a scanning type light emitting device. However, the light emitting device of the electronic device 1000 is not limited to the beam steering device 1010. In another example, the electronic device 1000 may include a flash type light emitting device instead of the beam steering device 1010 or together with the beam steering device 1010. A flash-type light emitting device may radiate light to a region including an entire field of view at once without a scanning process.

The light steered by the beam steering device 1010 may return to the electronic device 1000 after being reflected by the subject. The electronic device 1000 may include a detector 1030 for detecting light reflected by the subject. The detector 1030 may include a plurality of light detection devices and may further include other optical members. The plurality of light detection devices may include any one of the single photon detection devices 10 to 30 described above. In addition, the electronic device 1000 may further include a circuit unit 1020 connected to at least one of the beam steering device 1010 and the detection unit 1030. The circuit unit 1020 may include a calculation unit that acquires and calculates data, and may further include a driving unit and a control unit. In addition, the circuit unit 1020 may further include a power supply unit and a memory.

Although the case where the electronic device 1000 includes the beam steering device 1010 and the detection unit 1030 in one device is shown, the beam steering device 1010 and the detection unit 1030 are not provided as one device. The beam steering device 1010 and the detection unit 1030 may be provided separately in devices. In addition, the circuit unit 1020 may be connected to the beam steering device 1010 or the detection unit 1030 through conductive lineless communication without being conductive lined.

The electronic device 1000 according to the above-described embodiment may be applied to various electronic devices. As an example, the electronic device 1000 may be applied to a Light Detection And Ranging (LiDAR) device. The LiDAR device may be a phase-shift type device or a time-of-flight (TOF) type device. In addition, the avalanche photodetection devices 10 to 30 according to the embodiment or the electronic device 1000 including the same may be used in smart phones, wearable devices (glasses-type devices realizing augmented reality and virtual reality, etc.), and the Internet of Things (Internet of Things). IoT) devices, home appliances, tablet PCs (personal computers), PDAs (personal digital assistants), PMPs (portable multimedia players), navigation, drones, robots, unmanned vehicles, self-driving cars, and Advanced Drivers Assistance System (ADAS).

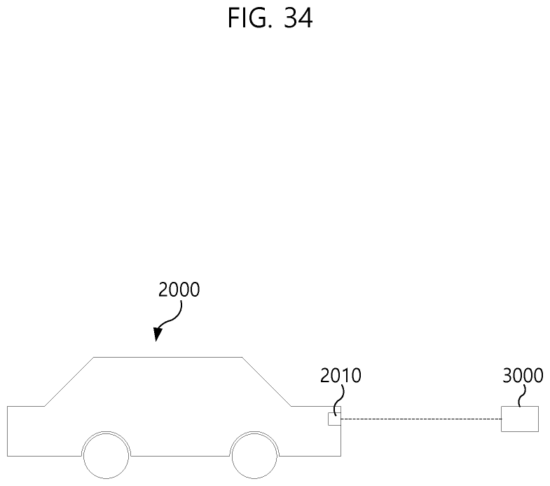

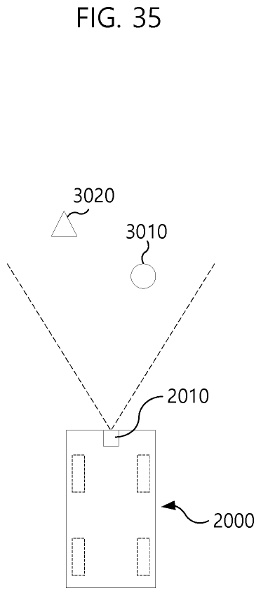

FIGS. 34 and 35 are conceptual diagrams illustrating cases in which a LiDAR device according to an exemplary embodiment is applied to a vehicle.

Referring to FIGS. 34 and 35, a LiDAR device 2010 may be applied to a vehicle 2000. Information on the subject 3000 may be obtained using a LiDAR device 2010 applied to a vehicle. The vehicle 2000 may be an automobile having an autonomous driving function. The LiDAR device 2010 may detect an object or person, ie, the subject 3000, in the direction in which the vehicle 2000 travels. The LiDAR device 2010 may measure the distance to the subject 3000 using information such as a time difference between a transmission signal and a detection signal. The LiDAR device 2010 may obtain information about a near subject 3010 and a far subject 3020 within a scanning range. The LiDAR device 2010 may include the electronic device 1000 described with reference to FIG. 33. It is illustrated that a LiDAR device 2010 is disposed in front of the vehicle 2000 to detect the subject 3000 in the direction in which the vehicle 2000 is traveling, but this is not limiting. In another example, the LiDAR device 2010 may be disposed at a plurality of locations on the vehicle 2000 to detect all subjects 3000 around the vehicle 2000. For example, four LiDAR devices 2010 may be disposed at the front, rear, and both sides of the vehicle 2000, respectively. In another example, the LiDAR device 2010 is disposed on the roof of the vehicle 2000 and rotates to detect subjects 3000 around the vehicle 2000.

The above descriptions are specific examples for carrying out the present invention. In addition to the above-described embodiments, the present invention will also include embodiments that can be simply or easily changed. In addition, the present invention will also include techniques that can be easily modified and practiced using the embodiments. Therefore, the scope of the present invention should not be limited to the above-described embodiments and should not be defined, and should be defined by those equivalent to the claims of this invention as well as the claims to be described later.

What is claimed is:

1. An avalanche photodetection device comprising:
A photodetection layer,
wherein the photodetection layer includes a first well, a heavily doped region provided on the first well, and an anode contact spaced apart from the heavily doped region,
wherein a conductivity type of the first well and the anode contact is p-type,
wherein a conductivity type of the heavily doped region is n-type,
wherein the heavily doped region is configured to be biased with a positive bias;
wherein the anode contact is configured to output a signal.

2. The avalanche photodetection device of claim 1, wherein the anode contact surrounds the heavily doped region.

3. The avalanche photodetection device of claim 1, wherein the photodetection layer further includes a second well provided between the first well and the heavily doped region,
wherein a conductivity type of the second well is n-type,
wherein a doping concentration of the second well is lower than a doping concentration of the heavily doped region,
wherein the first well and the second well are directly contact with each other to form a depletion region.

4. The avalanche photodetection device of claim 3, wherein the second well extends to a region between the heavily doped region and the anode contact.

5. The avalanche photodetection device of claim 4, wherein the first well extends to a region between the second well and the anode contact.

6. The avalanche photodetection device of claim 1, wherein the photodetection layer further includes a relief region directly contacting the contact,
wherein a conductivity type of the relief region is p-type,
wherein a doping concentration of the relief region is lower than a doping concentration of the contact and higher than a doping concentration of the first well.

7. The avalanche photodetection device of claim 6, wherein the photodetection layer further includes an additional relief region provided on a bottom surface of the relief region,
wherein a conductivity type of the additional relief region is p-type,
wherein the additional relief region is formed to a position deeper than the first well.

8. The avalanche photodetection device of claim 1, wherein the photodetection layer further includes a guard ring extending from a region on a side surface of the heavily doped region to a region on a side surface of the first well,
wherein a conductivity type of the guard ring is n-type,
wherein a doping concentration of the guard ring is lower than a doping concentration of the heavily doped region.

9. The avalanche photodetection device of claim 1, further comprising:
a control layer provided on the photodetection layer,
wherein the control layer includes a first circuit configured to bias the heavily doped region, and a second circuit configured to output the signal from the contact.

10. The avalanche photodetection device of claim 9, further comprising:
a connection layer provided between the control layer and the photodetection layer,
wherein the connecting layer includes a first conductive line configured to electrically connect the heavily doped region and the first circuit, and a second conductive line configured to electrically connect the anode contact and the second circuit.

11. An electronic device comprising:
an avalanche photodetection device including a photodetection layer,
wherein the photodetection layer includes a first well, a heavily doped region provided on the first well, and an anode contact spaced apart from the heavily doped region,
wherein the first well and the anode contact have a p-type conductivity type, the heavily doped region has an n-type conductivity, the heavily doped region is configured to be biased with a positive bias, and the anode contact is configured to output a signal.

12. A LiDAR device comprising:
an electronic device including an avalanche photodetection device,
wherein the avalanche photodetection device includes a photodetection layer,
wherein the photodetection layer includes a first well, a heavily doped region provided on the first well, and an anode contact spaced apart from the heavily doped region,
wherein the first well and the anode contact have a p-type conductivity type, the heavily doped region has an n-type conductivity, the heavily doped region is configured to be biased with a positive bias, and the anode contact is configured to output a signal.
